(19) United States
(12) Patent Application Publication
(10) Pub. No.: US 2014/0159554 A1
(43) Pub. Date: Jun. 12, 2014

(54) SERVER CABINET

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventors: MING-YU LIU, Shenzhen (CN); AN-GANG LIANG, Shenzhen (CN)

(73) Assignees: HON HAI PRECISION INDUSTRY CO., LTD, New Taipei (TW); HONG FU JIN PRECISION INDUSTRY (ShenZhen) CO., LTD, Shenzhen (CN)

(21) Appl. No.: 13/723,212

(22) Filed: Dec. 21, 2012

(30) Foreign Application Priority Data
Dec. 11, 2012 (CN) 201210530277.6

(51) Int. Cl. H05K 7/14

(52) U.S. Cl. CPC H05K 7/1488
USPC 312/223.2

(57) ABSTRACT

A server cabinet includes a rack, a bracket, and a switch. Two first poles are formed at a front end of the rack, and two second poles are formed at a rear end of the rack. A connection plate is connected between each first pole and the corresponding second pole in alignment with the first pole. A bracket is detachably fastened between the connection plates. A front end of the switch is fastened to the first poles, and a rear end of the switch is supported on the bracket.

### BACKGROUND

1. Technical Field

The present disclosure relates to a server cabinet.

2. Description of Related Art

In a server cabinet, a front end of a switch unit is generally fastened to a rack of the cabinet by screws. However, if the switch is long and heavy, a rear end of the switch tilts and damages the bonding by screws between the front end of the switch unit and the cabinet.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a server cabinet.

FIG. 2 is a partial, exploded, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

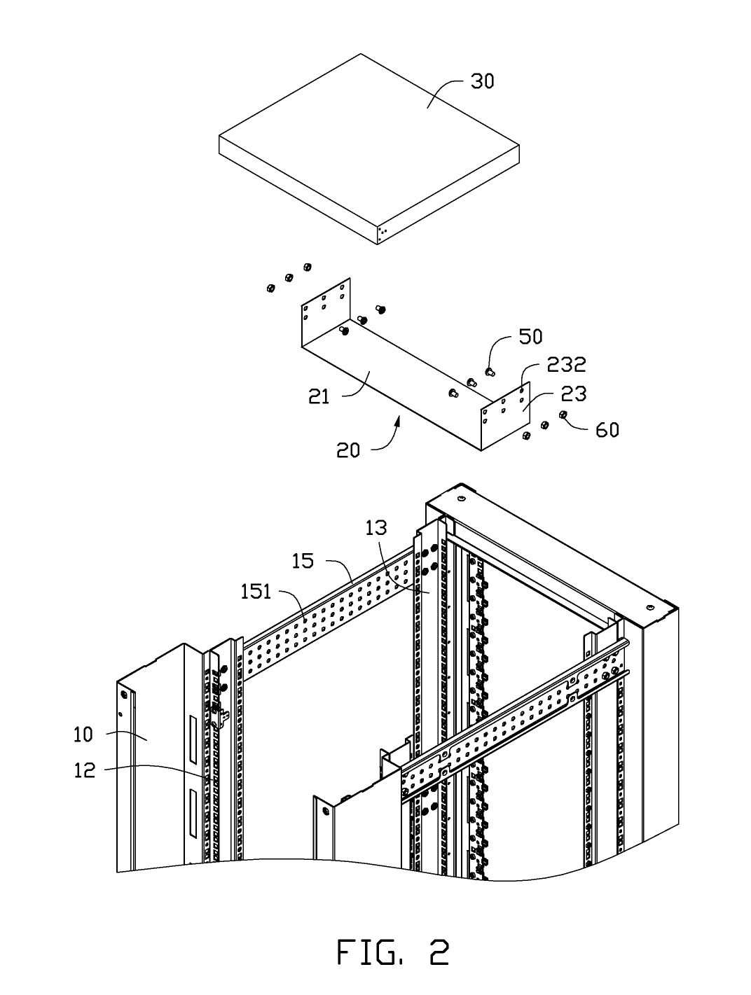

FIG. 2 shows an exemplary embodiment of a server cabinet. The server cabinet includes a rack 10, a bracket 20, and a switch 30.

Two first poles 12 are formed at opposite sides of a front end of the rack 10. Two second poles 13 are formed at opposite sides of a rear end of the rack 10, respectively aligning with the first poles 12. A connection plate 15 is connected between tops of each first pole 12 and the corresponding second pole 13 in a substantially perpendicular manner. Three rows of first through holes 151 are defined in each connection plate 15.

The bracket 20 includes a bottom plate 21 and two mounting plates 23 extending up from opposite ends of the bottom plate 21 in a substantially perpendicular manner. Two rows of second through holes 232 are defined in an upper portion of each mounting plate 23. The number of each row of first through holes 151 is more than the number of each row of second through holes 232. In the embodiment, the number of each row of second through holes 232 is three.

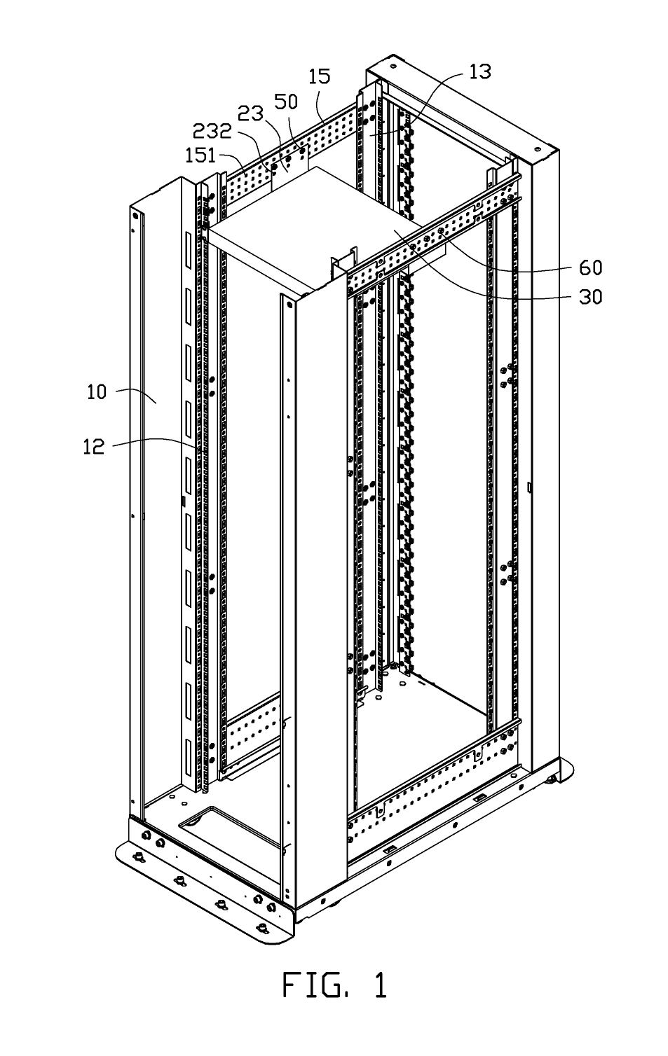

FIG. 1 shows in assembly. The bracket 20 is placed between the connection plates 15. One row of the second through holes 232 of each mounting plate 23 is aligned with three of one row of the first through holes 151 of the corresponding connection plate 15. Three screws 50 extend through the one row of the second through holes 232, the corresponding first through holes 151, and engage in three nuts 60. A rear end of the switch 30 is placed on the bottom plate 21, and a front end of the switch 30 is fastened to the first poles 12.

When a switch, which is longer than the switch 30 needed to be mounted to the rack 10, the bracket 20 is fastened to rear ends of the connection plates 15. When another switch, which is shorter than the switch 30 is needed to be mounted to the rack 10, the bracket 20 is fastened to middle portions or front portions of the connection plates 15.

Because each connection plate 15 defines three rows of first through holes 151 and each mounting plate 23 defines two rows of second through holes 232, the switch 30 can be fastened at different heights of the rack 10. If the switch 30 needs to be fastened at a relative high position, the bottom row of the second through holes 232 of each mounting plate 23 is aligned with three of the top row of the first through holes 151 of the corresponding connection plate 15, and the mounting plate 23 is fastened to the corresponding connection plate 15 with the screws 50 and nuts 60. If the switch 30 needs to be fastened at a relative low position, the top row of second through holes 232 of each mounting plate 23 is aligned with three of the bottom row of the first through holes 151 of the corresponding connection plate 15, and the mounting plate 23 is fastened to the corresponding connection plate 15 with the screws 50 and nuts 60

In a second embodiment, the nuts 60 are omitted, the first through holes 151 are screw holes. Each screw 50 extends through the corresponding second through hole 232 and engages in the corresponding first through hole 151.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A server cabinet, comprising:
a rack comprising two first poles formed at a front end of the rack, two second poles formed at a rear end of the rack, and two connection plates respectively connected between the first poles and the second poles and in alignment with each other;
a bracket detachably fastened between the connection plates; and
a switch, a front end of the switch fastened to the first poles, a rear end of the switch supported on the bracket.

2. The server cabinet of claim 1, wherein the bracket comprises a bottom plate for supporting the rear end of the switch and two mounting plates formed at opposite ends of the bottom plate, the mounting plates are detachably fastened to the connection plates respectively.

3. The server cabinet of claim 2, wherein the mounting plates extending up from the opposite ends of the bottom plate in a substantially perpendicular manner.

4. The server cabinet of claim 2, wherein each connection plate is connected between the corresponding first pole and second pole in a substantially perpendicular manner

5. The server cabinet of claim 2, wherein each connection plate defines a row of first through holes, each mounting plate defines a row of second through holes, a number of the first through holes is more than a number of the second through holes, the second through holes of each mounting plate are aligned with the corresponding first through holes of the corresponding connection plate, a plurality of screws extends through the second through holes and the corresponding first through holes to fasten the mounting plate to the corresponding connection plate.

6. The server cabinet of claim 2, wherein each connection plate defines a plurality of rows of first through holes, each mounting plate defines a row of second through holes, the number of each row of the first through holes is more than the number of the second through holes, the second through holes of each mounting plate are aligned with the corresponding row of the first through holes of the corresponding connection plate, a plurality of screws extends through the second through holes and the corresponding first through holes to fasten the mounting plate to the corresponding connection plate.

7. The server cabinet of claim 2, wherein each connection plate defines a plurality of rows of first through holes, each mounting plate defines a plurality of rows of second through holes, the number of each row of the first through holes is more than the number of each row of the second through holes, one row of the second through holes of each mounting plate is aligned with one row of the first through holes of the corresponding connection plate, a plurality of screws extends through the one row of the second through holes and the corresponding first through holes to fasten the mounting plate to the corresponding connection plate.
